(19) United States
(12) Patent Application Publication
(10) Pub. No.: US 2026/0047171 A1
(43) Pub. Date: Feb. 12, 2026

(54) SEMICONDUCTOR DEVICE AND METHOD FOR FABRICATING SAME

(71) Applicant: Hangzhou HFC Semiconductor Co., Hangzhou (CN)

(72) Inventors: Qilu LI, Hangzhou (CN); Hao ZHANG, Hangzhou, Zhejiang (CN); Cheng GAO, Hangzhou (CN)

(21) Appl. No.: 18/946,443

(22) Filed: Nov. 13, 2024

(30) Foreign Application Priority Data
Aug. 12, 2024 (CN) 202411095540.2

(51) Int. Cl. H01L 29/417; H01L 29/49; H01L 29/66

(52) U.S. Cl. CPC H10D 64/254; H10D 62/021; H10D 64/664

(57) ABSTRACT

A semiconductor device and a method for fabricating the device are disclosed. The semiconductor device includes a substrate and a dielectric layer formed on the substrate. A trench is formed in the dielectric layer, and a conductive structure is formed in the trench. The conductive structure includes a barrier layer and a metal contact structure. The barrier layer covers a bottom wall of each trench, and the metal contact structure is located on the barrier layer and fills the trench. The metal contact structure is made of a single metal material.

### CROSS-REFERENCE TO RELATED APPLICATION

This application claims the priority of Chinese patent application number 202411095540.2, filed on Aug. 12, 2024 and entitled “SEMICONDUCTOR DEVICE AND METHOD FOR FABRICATING SAME”, the entire contents of which are incorporated herein by reference.

### TECHNICAL FIELD

The present invention relates to the field of semiconductor manufacturing and, in particular, to a semiconductor device and a method for fabricating the device.

### BACKGROUND

In the current advanced semiconductor manufacturing processes, the formation of a metal contact structure in the middle-end-of-line (MEOL) involves the steps as described below.

As shown in FIG. 1, a substrate 10 is first provided, and a gate structure G is then formed on the substrate 10, as well as a source S and a drain are formed in the substrate 10 on opposite sides of the gate structure G. A first dielectric layer 11 is formed on the substrate 10, which covers the gate structure G. A bottom trench 12 is formed in the first dielectric layer 11, exposing the gate structure G, the source S and the drain. A metal layer 21 and a metal barrier layer 22 are sequentially deposited over the inner surface of the bottom trench 12. The first dielectric layer 11 includes a first portion formed on the substrate 10 outside the gate structure, a second portion formed on the first portion and a third portion formed on the second portion. Both the first and third portions are silicon oxide, and the second portion is silicon nitride. Both the metal layer 21 and the metal barrier layer 22 are thick above sidewalls of the trench. As shown in FIG. 2, an annealing process is then carried out, in which the metal layer 21 reacts with the substrate 10 to form a metal silicide layer 13 on the surface of the source S and the drain. As shown in FIG. 3, a physical vapor deposition (PVD) or chemical vapor deposition (CVD) process is carried out to form a cobalt liner layer and a cobalt seed layer over inner surface of the bottom trench 12, and cobalt is then filled in the bottom trench 12 by electrochemical plating (ECP), forming a metal contact film 23′, the metal contact film 23′ also covers the first dielectric layer 11 outside the bottom trench 12. As shown in FIG. 4, cobalt above the first dielectric layer 11 is then removed by chemical mechanical polishing (CMP). This results in formation of a first conductive contact 23 and thinning of the first dielectric layer 11. As shown in FIG. 5, subsequently, a second dielectric layer 14 is formed on the first dielectric layer 11, and a top trench 15 is formed in the second dielectric layer 14. The top trench 15 is above and in communication with the bottom trench 12 so that the first conductive contact 23 in the bottom trench 12 is exposed at the bottom of the top trench 15. A critical dimension (width) of the top trench 15 is greater than a width of the bottom trench 12. The second dielectric layer 14 includes a lower silicon nitride layer and an upper silicon oxide layer. As shown in FIG. 6, tungsten is filled in the top trench 15 to form a second conductive contact 24. The first conductive contact 23 and the second conductive contact 24 make up the metal contact structure.

This structure is associated with the following problems:
1. Due to a small width of the bottom trench, its opening size tends to be affected by all the deposition processes for forming the metal layer, the metal barrier layer, the cobalt liner layer and the cobalt seed layer, leaving a limited process window for the ECP process for filling cobalt.
2. The metal barrier layer is titanium nitride, which increases resistance of the first conductive contact in the bottom trench and additionally narrows the process window for the ECP process.
3. Cobalt is highly active, leading to more stringent compatibility requirements on processes involving this material (deposition, electroplating, etching, cleaning and CMP) and increasing their complexity. Moreover, use of cobalt is associated with a higher reliability risk.
4. The different conductive materials in the bottom and top trenches lead to increased resistance of the metal contact structure.

### SUMMARY OF THE INVENTION

It is an object of the present invention to provide a semiconductor device and a method for fabricating the device, which overcome the problems as described above.

Accordingly, the present invention provides a semiconductor device comprising a substrate and a first dielectric layer formed on the substrate, wherein the first dielectric layer is provided with trenches, wherein a conductive structure is formed in each trench, wherein the conductive structure comprises a barrier layer and a metal contact structure, wherein the barrier layer covers a bottom wall of the trench, and wherein the metal contact structure is formed on the barrier layer and fills the trench.

The metal contact structure is made of a single metal material.

In another aspect, the present invention provides a method for fabricating a semiconductor device, comprising the steps of:
providing a substrate, wherein a first dielectric layer is formed on the substrate and trenches are formed in the first dielectric layer; and
forming conductive structures in the trenches, each conductive structure comprising a barrier layer and a metal contact structure, the barrier layer covering a bottom wall of each trench, the metal contact structure formed on the barrier layer and filling the trench, the metal contact structure made of a single metal material.

The present invention has the following surprising benefits over the prior art:

It provides a semiconductor device and a method for fabricating the device. The semiconductor device includes a substrate and a first dielectric layer formed on the substrate. A trench is formed in the first dielectric layer, and a conductive structure is formed in the trench. The conductive structure includes a barrier layer and a metal contact structure. The barrier layer covers a bottom wall of the trench, and the metal contact structure is formed on the barrier layer and fills the trench. The metal contact structure is made of a single metal material. Since the barrier layer is formed only on the bottom wall of the trench, but not on any side wall thereof, filling can be achieved more easily, and the conductive structure has reduced resistance. Since the metal contact structure is formed of a single metal material, the problems arising from the presence of two different metal materials in the direction of thickness of the trench can be circumvented, including more difficult process integration and increased resistance at an interface where the two metal materials directly contact with each other. Thus, a further decrease in resistance can be achieved.

### BRIEF DESCRIPTION OF THE DRAWINGS

FIG. 1 is a schematic structural view of a substrate in a semiconductor device.

FIG. 2 is a schematic structural view of a semiconductor device resulting from formation of a metal silicide layer.

FIG. 3 is a schematic structural view of a semiconductor device resulting from filling of cobalt in a bottom trench.

FIG. 4 is a schematic structural view of a semiconductor device resulting from formation of a first conductive contact.

FIG. 5 is a schematic structural view of a semiconductor device resulting from formation of a top trench.

FIG. 6 is a schematic structural view of a semiconductor device.

FIG. 7 is a schematic structural view of a substrate provided in accordance with an embodiment of the present invention.

FIG. 8 is a schematic diagram showing a structure resulting from formation of a barrier film according to an embodiment of the present invention.

FIG. 9 is a schematic diagram showing a structure resulting from processing of side walls of trenches using wet etching according to an embodiment of the present invention.

FIG. 10 is a schematic diagram showing a structure resulting from filling of an organic material layer according to an embodiment of the present invention.

FIG. 11 is a schematic diagram showing a structure resulting from removal of the organic material layer formed above a first dielectric layer according to an embodiment of the present invention.

FIG. 12 is a schematic diagram showing a structure resulting from removal of films formed above the first dielectric layer according to an embodiment of the present invention.

FIG. 13 is a schematic diagram showing a structure resulting from removal of the organic material layer in the trenches according to an embodiment of the present invention.

FIG. 14 is a schematic diagram showing a structure resulting from growth of a conductive metal material according to an embodiment of the present invention.

FIG. 15 is a schematic structural view of a semiconductor device according to an embodiment of the present invention.

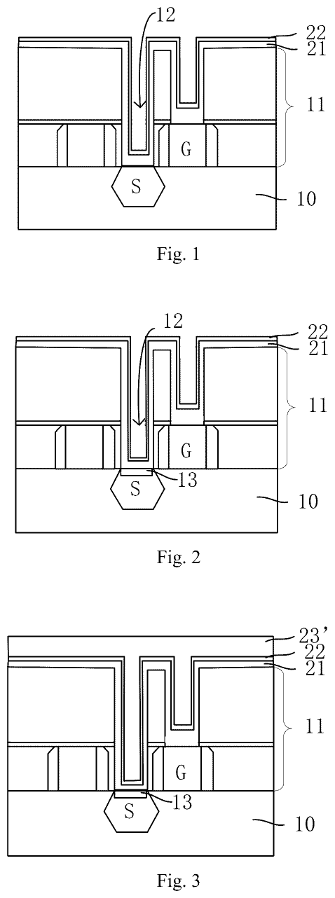

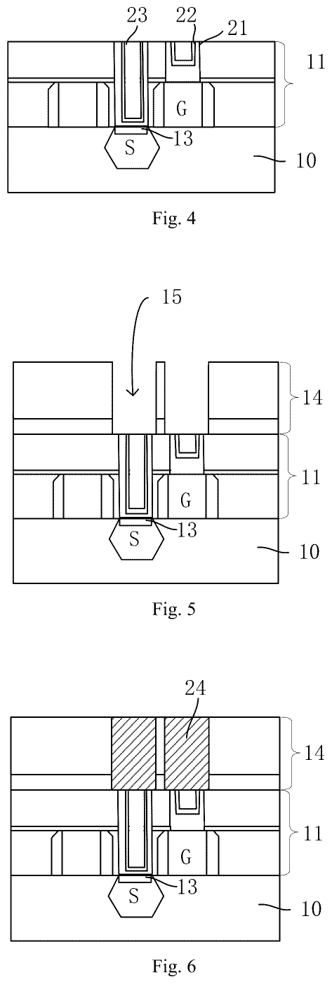

In FIGS. 1 to 6,
10, a substrate; 11, a first dielectric layer; 12, a bottom trench; 13, a metal silicide layer; 14, a second dielectric layer; 15, a top trench; 21, a metal layer; 22, a metal barrier layer; 23′, a metal contact film; 23, a first conductive contact; and 24, a second conductive contact.

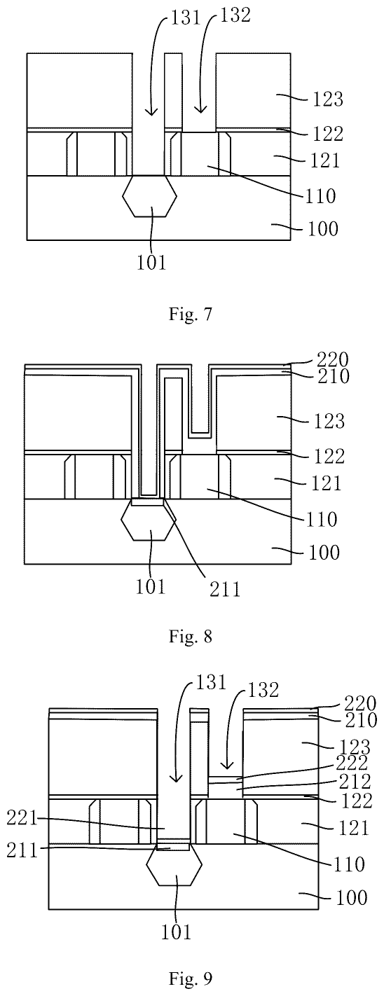

In FIGS. 7 to 15,
100, a substrate; 101, a source region; 110, a gate structure; 121, a bottom dielectric layer; 122, an intermediate stop layer; 123, a top dielectric layer; 131, a first trench; 132, a second trench; 210, a metal material film; 211, a metal silicide film; 212, a bottom metal film; 220, a barrier film; 221, a first barrier layer; 222, a second barrier layer; 230, a conductive metal material; 231, a first metal contact structure; 232, a second metal contact structure; and 300, an organic material layer.

### DETAILED DESCRIPTION

Semiconductor devices and methods according to the present invention will be described in greater detail below with reference to the accompanying drawings, which present preferred embodiments thereof. It will be understood that those skilled in the art can make changes to the invention disclosed herein while still obtaining the beneficial results thereof. Therefore, the following description shall be construed as being intended to be widely known by those skilled in the art rather than as limiting the invention.

For the sake of clarity, not all features of an actual implementation are described in this specification. In the following, description and details of well-known functions and structures are omitted to avoid unnecessarily obscuring the invention. It should be appreciated that in the development of any such actual implementation, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking for those of ordinary skill in the art.

Advantages and features of the present invention will become more apparent from the following description of specific embodiments thereof taken in conjunction with the accompanying drawings. Note that the figures are provided in a very simplified form not necessarily drawn to exact scale for the only purpose of helping in describing the embodiments in a convenient and clear way.

As shown in FIG. 15, embodiments of the present invention provide a semiconductor device including a substrate and a first dielectric layer formed on the substrate. In the first dielectric layer, there are trenches and conductive structures in the trenches. The conductive structures each include a barrier layer and a metal contact structure. The barrier layer covers a bottom wall of the trench, and the metal contact structure is formed on the barrier layer and fills the trench. The metal contact structure is made of a single metal material.

In these embodiments, the barrier layer is formed only on the bottom wall of the trench, but not on any side wall of the trench. Therefore, it can be more easily formed by filling and results in reduced resistance of the resulting conductive structure. Since the metal contact structure is formed of a single metal material, the problems arising from the presence of two different metal materials in the direction of thickness of the trench can be circumvented, including more difficult process integration and increased resistance at an interface where the two metal materials directly contact with each other. Thus, a further decrease in resistance can be achieved.

In detail, the substrate 100 is made of a semiconductor material, such as silicon, silicon carbide, silicon germanium, a III-V material or a combination thereof. For example, it may be a silicon-on-insulator (SOI) or germanium-on-insulator (GOI) substrate.

There are gate structures 110 formed on the substrate 100, as well as source regions 101 and drain regions formed in the substrate 100 on opposite sides of the gate structures 110. The first dielectric layer is formed on the substrate 100. The first dielectric layer covers the gate structures 110 and the substrate 100 outside the gate structures 110. The first dielectric layer functions to provide support to the conductive structures. The first dielectric layer is made of a material including one or more of silicon oxide, silicon nitride, silicon carbonitride, silicon boronitride, silicon carbon oxynitride and silicon oxynitride.

In one embodiment, the first dielectric layer includes a bottom dielectric layer 121, an intermediate stop layer 122 and a top dielectric layer 123. The bottom dielectric layer 121 covers the substrate 100 outside the gate structures 110 and has a surface flush with surfaces of the gate structures 110. The intermediate stop layer 122 is formed on the gate structures 110 and the bottom dielectric layer 121, and the top dielectric layer 123 is formed on the intermediate stop layer 122. Both the bottom dielectric layer 121 and the top dielectric layer 123 are silicon oxide, and the intermediate stop layer 122 is silicon nitride.

The trenches formed in the first dielectric layer include a first trench 131 and a second trench 132. The first trench 131 extends through the top dielectric layer 123, the intermediate stop layer 122 and the bottom dielectric layer 121 and exposes the substrate 100 in which source 101 and drain regions are formed. The second trench 132 extends through the top dielectric layer 123 and the intermediate stop layer 122 and exposes an upper surface of a gate structure 110.

A metal silicide film 211 is formed on a bottom wall of the first trench 131, and a bottom metal film 212 is formed on a bottom wall of the second trench 132. The metal silicide film 211 is, for example, titanium silicide. The bottom metal film 212 is, for example, titanium.

The conductive structures include a first conductive structure formed in the first trench 131 and a second conductive structure formed in the second trench 132. The first and second conductive structures are of the same structure (same cross-section shape) but have different heights.

In detail, the first conductive structure includes a first barrier layer 221 and a first metal contact structure 231. The first barrier layer 221 is formed on the metal silicide film 211, and the first metal contact structure 231 is formed on the first barrier layer 221 and fills the first trench 131. The first metal contact structure 231 is made of a single metal material.

The second conductive structure includes a second barrier layer 222 and a second metal contact structure 232. The second barrier layer 222 is formed on the bottom metal film 212, and the second metal contact structure 232 is formed on the second barrier layer 222 and fills the second trench 132. The second metal contact structure 232 is made of a single metal material.

The first barrier layer 221 and the second barrier layer 222 are made of the same material and have the same thickness. The material of each of the first barrier layer 221 and the second barrier layer 222 is, for example, titanium nitride. The first metal contact structure 231 and the second metal contact structure 232 are made of the same material. Since the first trench 131 has a greater depth than the second trench 132, the first metal contact structure 231 has a greater height than the second metal contact structure 232. The material of the first metal contact structure 231 and the second metal contact structure 232 is tungsten, for example.

In one embodiment, side walls of the first trench 131 and the second trench 132 are not covered with any barrier layer. This allows the resulting conductive structures to have reduced resistance. Additionally, the conductive structures do not contain cobalt and therefore can be formed using a simpler process with less stringent requirements. Further, the reliability risk associated with the use of cobalt can be avoided. According to embodiments of the present invention, the conductive structures are made simply of tungsten, instead of upper tungsten portion and lower cobalt portion as is conventional. This avoids the introduction of additional resistance by an interface between cobalt and tungsten, thereby additionally reducing the resistance of the resulting conductive structures. Furthermore, according to embodiments of the present invention, only the first dielectric layer is formed (in contrast to both the first and second dielectric layers being formed on the substrate 100 in the conventional method), and the metal contact structures are made of a single metal material, simplifying the structure of the resulting semiconductor device. Embodiments of the present invention also provide a method for fabricating a semiconductor device, which includes the steps detailed below.

In step S1, a substrate is provided, on which a first dielectric layer with trenches is formed.

In step S2, conductive structures are formed in the trenches. Each of the conductive structures includes a barrier layer and a metal contact structure. The barrier layer covers a bottom wall of the trench, and the metal contact structure ia formed on the barrier layer and fills the trench. The metal contact structure is formed of a single metal material.

A method for fabricating a semiconductor device according to embodiments of the present invention is described in detail below with reference to FIGS. 7 to 15.

As shown in FIG. 7, in step S1, a substrate is provided, on which a first dielectric layer with trenches is formed.

The step 1 further includes the sub-steps detailed below.

At first, the substrate is provided, the substrate 100 made of a semiconductor material, such as silicon, silicon carbide, silicon germanium, a III-V material or a combination thereof. For example, it may be an SOI or substrate. Gate structures 110 are formed on the substrate 100, and source regions 101 and drain regions are formed in the substrate 100 on opposite sides of the gate structures 110. The first dielectric layer is formed on the substrate 100. The first dielectric layer covers the gate structures 110 and the substrate 100 outside the gate structures 110. The first dielectric layer functions to provide support to the conductive structures. The first dielectric layer is made of a material including one or more of silicon oxide, silicon nitride, silicon carbonitride, silicon boronitride, silicon carbon oxynitride and silicon oxynitride.

According to embodiments of the present invention, the first dielectric layer includes a bottom dielectric layer 121, an intermediate stop layer 122 and a top dielectric layer 123. The bottom dielectric layer 121 covers the substrate 100 outside the gate structures 110 and has a surface flush with surfaces of the gate structures 110. The intermediate stop layer 122 is formed on the gate structures 110 and the bottom dielectric layer 121, and the top dielectric layer 123 is formed on the intermediate stop layer 122. Both the bottom dielectric layer 121 and the top dielectric layer 123 are silicon oxide, and the intermediate stop layer 122 is silicon nitride.

Next, the trenches are formed in the first dielectric layer, which include a first trench 131 and a second trench 132. The first trench 131 extends through the top dielectric layer 123, the intermediate stop layer 122 and the bottom dielectric layer 121 and exposes the substrate 100 in which the source 101 and drain regions formed. The second trench 132 extends through the top dielectric layer 123 and the intermediate stop layer 122 and exposes an upper surface of a gate structure 110.

As shown in FIGS. 8 to 15, in step S2, the conductive structures are formed in the trenches, each of which includes a barrier layer and a metal contact structure. The barrier layer covers a bottom wall of the trench, and the metal contact structure is formed on the barrier layer and fills the trench. The metal contact structure is formed of a single metal material.

The step 2 further includes the sub-steps detailed below.

As shown in FIG. 8, first of all, a radio frequency physical vapor deposition (RFPVD) process is performed to form a thin metal material film 210 lining the trenches. The metal material film 210 covers inner walls (i.e., bottom and side walls) of the trenches. That is, the metal material film 210 covers the inner walls (bottom and side walls) of the first trench 131 and the inner walls (bottom and side walls) of the second trench 132. The resulting metal material film 210 has a much smaller thickness above the side walls of the trenches than above the bottom walls of the trenches. In a particular example, the thickness of the metal material film 210 above the side walls is below one tenth of its thickness above the bottom walls. This facilitates the subsequent process for selectively removing the metal material film 210 on the side walls of the trenches. Examples of the material of the metal material film 210 may include, but are not limited to, titanium.

Subsequently, another RFPVD process is carried out to form a thin barrier film 220 over the metal material film 210. The resulting barrier film 220 has a much smaller thickness above the side walls of the trenches than above the bottom walls of the trenches. In a particular example, the thickness of the barrier film 220 above the side walls is below one tenth of its thickness above the bottom walls. This facilitates the subsequent process for selectively removing the barrier film 220 above the side walls of the trenches.

Afterwards, an annealing process is performed to induce a reaction between the metal material film 210 and the substrate 100, resulting in the formation of a metal silicide film 211 on the bottom wall of the first trench 131.

As shown in FIG. 9, a wet etching process is carried out to remove the metal material film 210 and the barrier film 220 above the side walls of the trenches. As a result, a metal silicide film 211 and a first barrier layer 221 are formed above the bottom wall of the first trench 131. Moreover, a bottom metal film 212 and a second barrier layer 222 are formed above the bottom wall of the second trench 132. At this time, metal material film 210 and the barrier film 220 are not present around openings of the first trench 131 and the second trench 132. In this way, during the formation of the metal contact structures, opening sizes of the first trench 131 and the second trench 132 are defined by their own widths, preventing the formation of any void or gap.

Since both the metal material film 210 and the barrier film 220 are much thinner above the side walls of the first trench 131 and the second trench 132, the wet etching process is allowed to use a low-concentration etchant solution or be performed for a short period of time and exerts a limited impact on the metal silicide film 211 and the first barrier layer 221 above the bottom wall of the first trench 131 and on the bottom metal film 212 and the second barrier layer 222 above the bottom wall of the second trench 132. That is, they experience controlled thickness loss in this process.

The etchant solution may be a solution of an ammonia-peroxide mixture (APM).

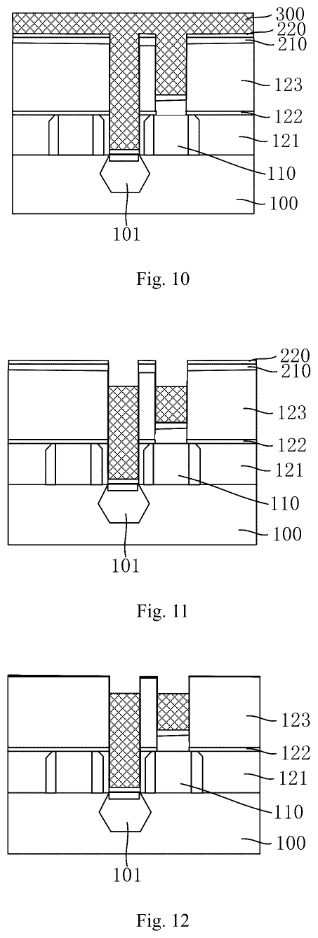

As shown in FIG. 10, the first trench 131 and the second trench 132 are both filled with an organic material layer 300, such as a photoresist layer. The resulting organic material layer 300 also covers the first dielectric layer.

As shown in FIG. 11, the organic material layer 300 formed on the first dielectric layer is etched away. At the same time, partial depths of the first trench 131 and the second trench 132 are exposed.

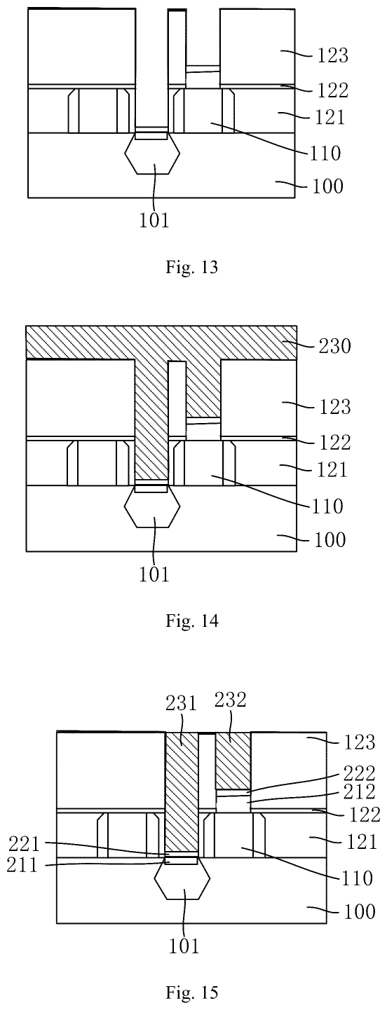

As shown in FIG. 12, another wet etching process is performed to remove the barrier film 220 and the metal material film 210 above the first dielectric layer, exposing the first dielectric layer. As shown in FIG. 13, the organic material layer 300 in the first trench 131 and the second trench 132 is removed.

As shown in FIG. 14, a conductive metal material 230 is selectively grown on both the first barrier layer 221 and the second barrier layer 222. The conductive metal material 230 grows upwards from the bottom of the first and second trenches until it fills the first trench 131 and the second trench 132 and covers the first dielectric layer. In this process, as the conductive metal material 230 can grow from the bottom upwards without being obstructed at all on the side walls of the trenches, no gap or void will be formed. The conductive metal material 230 may be metal tungsten, for example.

As shown in FIG. 15, a chemical mechanical polishing (CMP) process is then performed to remove the conductive metal material 230 on the first dielectric layer, to form a first metal contact structure 231 in the first trench 131 and a second metal contact structure 232 in the second trench 132. As a result, the conductive structures, including a first conductive structure and a second conductive structure, are formed. Upper surfaces of the conductive structures are flush with the surface of the first dielectric layer.

In comparison with the conventional technique, in which two CMP processes are performed and first and second dielectric layers are formed, the present invention involves the performance of only one CMP process and formation of only the first dielectric layer. Therefore, it reduces process complexity and simplifies the structure of the semiconductor device. Moreover, since the metal contact structures are made of a single metal material, the introduction of additional resistance by an interface between two different metal materials is circumvented. Further, the conductive structures do not contain cobalt and therefore can be formed at lower cost using a simpler process with less stringent requirements.

In summary, the present invention provides a semiconductor device and a method for fabricating the device. The semiconductor device includes a substrate and a first dielectric layer formed on the substrate. A trench is formed in the first dielectric layer, and a conductive structure is formed in the trench. The conductive structure includes a barrier layer and a metal contact structure. The barrier layer covers a bottom wall of the trench, and the metal contact structure is formed on the barrier layer and fills the trench. The metal contact structure is made of a single metal material. Since the barrier layer is formed only on the bottom wall of the trench, but not on any side wall thereof, filling can be achieved more easily, and the conductive structure has reduced resistance. Since the metal contact structure is formed of a single metal material, the problems arising from the presence of two different metal materials in the direction of thickness of the trench can be circumvented, including increased resistance at an interface where the two metal materials directly contact with each other. Thus, a further decrease in resistance can be achieved.

Further, it is understood that, as used herein, the terms “first”, “second” and the like are only meant to distinguish various components, elements, steps, etc. from each other and are not intended to indicate logical or sequential orderings thereof, unless otherwise indicated or specified.

It would be appreciated that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent alternatives and modifications made to the foregoing embodiments based on the substantive disclosure of the invention without departing from the scope thereof fall within the scope.

What is claimed is:

1. A method for forming a conductive structure on a substrate, comprising the steps of:
forming a dielectric layer on the substrate,
forming a trench in the dielectric layer;
depositing a metal material film in the trench by a first radio frequency physical vapor deposition (RFPVD) process, wherein the metal material film covers a bottom wall and a side wall of the trench;
depositing a barrier film over the metal material film by a second RFPVD process;
performing a wet etching process to remove a portion of the metal material film and a portion of the barrier film on the side wall of the trench, such that after the wet etching process, a remaining portion of the metal material film and a remaining portion of the barrier film cover the bottom wall of the trench only, wherein the remaining portion of the barrier film forms a barrier layer; and
selectively growing a conductive metal material on the barrier layer to fill the trench, the conductive metal material filled in the trench forming a conductive structure which comprises a single metal material.

2. The method of claim 1, wherein the first RFPVD process forms a metal material film having a thickness at the bottom wall of the trench much greater than a thickness over the side wall of the trench.

3. The method of claim 1, wherein the wet etching process is conducted by using a solution of an ammonia-peroxide mixture.

4. The method of claim 1, wherein the trench in the dielectric layer exposes a source or drain region of a transistor prefabricated in the substrate, and wherein the method further comprises, before the wet etching process:
conducting an annealing process to induce a reaction between the substrate and the metal material film that is formed on the bottom wall of the trench to form a metal silicide film on the bottom wall of the trench.

5. The method of claim 1, wherein the barrier layer is made of titanium nitride, and wherein the contact structure is made of tungsten.

6. A method for fabricating a semiconductor device, comprising the steps of:
providing a substrate,
forming a dielectric layer on the substrate,
forming at least one trench in the dielectric layer;
depositing a metal material film in each of the at least one trench by a first radio frequency physical vapor deposition (RFPVD) process, wherein the metal material film covers a bottom wall and a side wall of the trench;
depositing a barrier film over the metal material film by a second RFPVD process;
performing a wet etching process to remove a portion of the metal material film and a portion of the barrier film on the side wall of each trench, such that after the wet etching process, a remaining portion of the metal material film and a remaining portion of the barrier film cover the bottom wall of each trench only, wherein the remaining portion of the barrier film forms a barrier layer; and
selectively growing a conductive metal material on the barrier layer to fill the trench, the conductive metal material filled in each trench forming a metal contact structure which comprises a single metal material.

7. The method of claim 6, wherein the substrate has a gate structure formed thereon, and a source region and a drain region are formed in the substrate on opposite sides of the gate structure, wherein the dielectric layer covers the gate structure and the substrate outside the gate structure, wherein the dielectric layer comprises a bottom dielectric layer, an intermediate stop layer and a top dielectric layer, wherein the bottom dielectric layer covers the substrate outside the gate structure, wherein the bottom dielectric layer comprises a surface flush with a surface of the gate structure, wherein the intermediate stop layer is formed on the gate structure and the bottom dielectric layer, and wherein the top dielectric layer is formed on the intermediate stop layer.

8. The method of claim 7, wherein forming the at least one trench in the dielectric layer comprises forming a first trench and a second trench, wherein the first trench extends through the top dielectric layer, the intermediate stop layer and the bottom dielectric layer, and exposes a portion of the substrate where the source and drain regions are formed, and wherein the second trench extends through the top dielectric layer and the intermediate stop layer, and exposes an upper surface of the gate structure.

9. The method of claim 8, further comprising, prior to the wet etching process: performing an annealing process to induce a reaction between the portion of substrate and the metal material film that is formed on the bottom wall of the first trench, thereby forming a metal silicide film at the bottom wall of the first trench.

10. The method of claim 1, wherein the barrier layer is made of titanium nitride, and wherein the contact structure is made of tungsten.

11. A semiconductor device fabricated according to the method of claim 6, comprising a substrate and a dielectric layer formed on the substrate, wherein the dielectric layer has at least one trench formed therein, wherein at least one conductive structure is formed in the at least one trench, wherein each of the at least one conductive structure comprises a barrier layer and a metal contact structure, wherein the barrier layer covers a bottom wall of the corresponding trench, and wherein the metal contact structure is formed on the barrier layer and fills the trench, and
wherein the metal contact structure is made of a single metal material.

12. The semiconductor device of claim 11, wherein the substrate has a gate structure formed thereon and a source region and a drain region are provided in the substrate on opposite sides of the gate structure, wherein the dielectric layer covers the gate structure and the substrate outside the gate structure; and
wherein the dielectric layer comprises a bottom dielectric layer, an intermediate stop layer and a top dielectric layer, wherein the bottom dielectric layer covers the substrate outside the gate structure, wherein a surface of the bottom dielectric layer is flush with a surface of the gate structure, wherein the intermediate stop layer is formed on the gate structure and the bottom dielectric layer, and wherein the top dielectric layer is formed on the intermediate stop layer.

13. The semiconductor device of claim 12, wherein the at least one trench includes a first trench and a second trench, wherein the first trench extends through the top dielectric layer, the intermediate stop layer and the bottom dielectric layer and exposes a portion of the substrate where the source and drain regions are formed, wherein the second trench extends through the top dielectric layer and the intermediate stop layer and exposes an upper surface of the gate structure.

14. The semiconductor device of claim 13, wherein a metal silicide film is formed at a bottom wall of the first trench, and a bottom metal film is formed on a bottom wall of the second trench,
wherein the at least one conductive structure includes a first conductive structure in the first trench and a second conductive structure in the second trench, wherein the first conductive structure comprises a first barrier layer and a first metal contact structure, wherein the first barrier layer is formed on the metal silicide film, and wherein the first metal contact structure is formed on the first barrier layer and fills the first trench, and
wherein the second conductive structure comprises a second barrier layer and a second metal contact structure, wherein the second barrier layer is formed on the bottom metal film, and wherein the second metal contact structure is formed on the second barrier layer and fills the second trench.

15. The semiconductor device of claim 11, wherein the barrier layer is made of titanium nitride, and wherein the metal contact structure is made of tungsten.
